(19) United States
(12) Patent Application Publication
(10) Pub. No.: US 2010/0173441 A1
(43) Pub. Date: Jul. 8, 2010

(54) METHOD FOR PROCESSING ELONGATE SUBSTRATES AND SUBSTRATE SECURING APPARATUS

(75) Inventors: Andrew William Blakers, Kaleen ACT (AU); Klaus Johannes Weber, Aranda ACT (AU); Vernie Allan Everett, Kaleen ACT (AU)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Transform Solar Pty Ltd, Sydney NSW (AU)

(21) Appl. No.: 12/527,029

(22) PCT Filed: Feb. 15, 2007
(86) PCT No.: PCT/AU07/00154

§ 371 Date: Oct. 12, 2009

(51) Int. Cl. H01L 31/18; B32B 38/00; B29C 65/00; B23K 31/00; H01L 21/302; H01L 21/31; H01L 21/306; H01L 21/98; B32B 3/30; B23Q 7/00

(52) U.S. Cl. 438/57; 156/292; 156/272.2; 228/174; 438/758; 438/778; 438/689; 438/455; 428/156; 29/559; 257/E31.001; 257/E21.214; 257/E21.24; 257/E21.215; 257/E21.705

(57) ABSTRACT

A method for processing elongate substrates, including forming a plurality of parallel elongate openings (102) through a semiconductor wafer (104) to form a corresponding plurality of elongate substrates (106) between the openings, each of the elongate substrates (106) having opposite edges coplanar with opposite surfaces of the wafer, opposite faces (112) orthogonal to the wafer surfaces, and opposite ends by which the elongate substrates are interconnected; and applying securing means (402) to at least one of the opposite edges of each elongate substrate to engage the edges and thereby inhibit relative movement of the elongate substrates.

### FIELD OF THE INVENTION

This present invention relates to a method for processing elongate substrates and a substrate securing apparatus, and in particular a method for processing elongate substrates formed by a process such as that described in International Patent Application Publication No. WO 02/45143.

### BACKGROUND

In this specification, the term “elongate solar cell” refers to a solar cell of generally parallelepiped form and having a high aspect ratio in that its length l is substantially greater (typically some tens to hundreds of times larger) than its width w and its thickness t. Additionally, the width w of an elongate solar cell is substantially greater (typically four to one hundred times larger) than its thickness t. The length and width of a solar cell define the maximum available active or useable surface area for power generation (the active “face” or “faces” of the solar cell), whereas the length and thickness of a solar cell define the optically inactive longitudinal surfaces or “edges” of a cell. A typical elongate solar cell is 10-120 mm long, 0.5-5 mm wide, and 15-400 microns thick.

Elongate solar cells can be produced by processes such as those described in “HighVo (High Voltage) Cell Concept” by S. Scheibenstock, S. Keller, P. Fath, G. Willeke and E. Bucher, Solar Energy Materials & Solar Cells Vol. 65 (2001), pages 179-184 (“Scheibenstock”), and in International Patent Application Publication No. WO 02/45143 (“the Sliver patent application”). The latter document describes processes for producing a large number of thin (generally <150 μm) elongate silicon substrates from a single standard silicon wafer where the number and dimensions of the resulting thin elongate substrates are such that the total useable surface area is greater than that of the original silicon wafer. Such elongate substrates are also referred to as ‘sliver substrates.’ The word “SLIVER” is a registered trademark of Origin Energy Solar Pty Ltd, Australian Registration No. 933476. The Sliver patent application also describes processes for forming solar cells on sliver substrates, referred to as ‘sliver solar cells’. However, the word ‘sliver’ generally refers to a sliver substrate which may or may not incorporate one or more solar cells.

In general, elongate solar cells can be single-crystal solar cells or multi-crystalline solar cells formed on elongate substrates using essentially any solar cell manufacturing process. As shown in FIG. 1, elongate substrates are preferably formed in a batch process by machining (preferably by anisotropic wet chemical etching) a series of parallel elongate rectangular slots or openings 102 completely through a silicon wafer 104 to define a corresponding series of parallel elongate parallelepiped substrates or ‘slivers’ 106 of silicon between the openings 102. The length of the slots 102 is less than, but similar to, the diameter of the wafer 104 so that the elongate substrates or slivers 106 remain joined together by the remaining peripheral portion 108 of the wafer, referred to as the wafer frame 108. Each sliver 106 is considered to have two longitudinal edges 110 coplanar with the two wafer surfaces, two (newly formed) faces 112 perpendicular to the wafer surface, and two ends 114 attached to the wafer frame 108. As shown in FIG. 1, solar cells can be partially formed from the elongate substrates 106 while they remain retained by the wafer frame 108; the resulting elongate substrates 106 can then be separated from each other and from the wafer frame, and further processing performed if necessary, to provide a set of individual elongate solar cells. A large number of these elongate solar cells can be electrically interconnected and assembled together to form a solar power module, concentrator receiver, or other device.

When elongate substrates are formed in this way, the transverse width of the elongate slots and the elongate silicon substrates (slivers) in the plane of the wafer surface are both typically 0.05 mm, so that each sliver/slot pair effectively consumes a surface area of l×0.1 mm from the wafer surface, where l is the length of the elongate substrate. However, because the thickness of the silicon wafer is typically 0.5-2 mm, the surface area of each of the two newly formed faces of the sliver (perpendicular to the wafer surface) is l×0.5-2 mm, thus providing an increase in useable surface area by a factor of 5-20 relative to the original wafer surface (neglecting any useable surface area of the wafer frame).

There are strong economic reasons to maximise wafer utilisation and reduce the thickness of each sliver. For example, if the pitch—the distance between the centreline of each slot—is halved, but other parameters remain substantially unchanged, then twice as many sliver solar cells can be formed from the wafer, thus doubling the total active surface area for power generation, and halving the cost of producing each sliver cell. However, a likely consequence of reducing the pitch is that the sliver thickness will be similarly reduced. Due to their high length-to-width and width-to-thickness aspect ratios, despite being secured to the wafer frame 108 at each end, it has been found that slivers can easily bend in a direction perpendicular to their length and to their width directions (i.e., in a direction normal to the sliver faces), as shown by the arrows in the cross-sectional side view of FIG. 2. For example, FIG. 3 is a schematic plan view of a portion of slivers located approximately half way between the two opposite ends of the slivers, illustrating the bending that can occur, and that adjacent slivers 202 may even contact one another.

When a sliver bends and touches a neighbouring sliver, it may or may not stick to the neighbouring sliver, an instance of the phenomenon referred to in the micromachining field as stiction, and referred to in this context as “sliver sticking”. In practice, it has been found that neighbouring slivers can adhere to one another along part of their length, and may even form clumps of many slivers. A non-exhaustive list of factors that promote sticking include the following:
(i) weak atomic and molecular forces that cause attraction between the opposing faces of neighbouring slivers, including the formation of weak chemical bonds;
(ii) stress within the wafer, which can be relieved by sliver bending; and
(iii) the presence of dielectric materials that overhang the edges of each sliver; if these layers slide one under another, then they can become locked in place. These overhanging dielectric materials sometimes occur as a consequence of the slot etching process, whereby a masking dielectric is undercut more slowly than the substrate material.

During the etching of the slots 102, the slivers 106 are held firmly in place relative to one other and to the wafer frame 108 by the silicon remaining in the partially etched slots or trenches until the etched region reaches the other side of the wafer, or meets a trench being etched from the reverse side of the wafer 104, to form openings through the wafer. Once the openings have been formed, only the two opposing ends of each sliver are secured, and the sliver is otherwise free to bend along its length. Clearly, the degree of bending will be determined by factors such as the Young's modulus of the material of which the slivers are composed (typically silicon), and the length and thickness of the slivers. In order to successfully convert the sliver into a working solar cell, it is desirable that the slivers remain in mutually spaced and fixed positions relative to each other and relative to the wafer frame 108 during subsequent processing. In particular, if pairs or groups of slivers adhere to one another or break free from the wafer frame 108 during processing, then problems will arise. For example, many steps in the process of converting slivers into sliver solar cells require process chemicals to have good access to the faces of the slivers. These steps include wet chemical washing and rinsing, texturing, phosphorus or boron diffusion, oxidation and the deposition of dielectric and metal materials.

As described in the Sliver patent application the amount of sliver movement can be reduced by leaving residual silicon (“silicon bridges”) in the slots in order to hold the slivers apart from each other. Further fabrication processes can then be carried out. At or near the end of the solar cell fabrication process, the silicon bridges must be removed by some means. This could be by fracturing or laser scribing.

It is highly desirable to keep the cross-sectional area of the silicon bridges to a minimum while maintaining adequate strength to resist sliver movement. One reason for this is that when a silicon bridge is cut or fractured to separate the individual slivers, the region of the cut or fracture provides a site for substantial electron-hole recombination, thus reducing solar cell efficiency. Recombination can arise at least in part from regional damage to the crystal in the form of microcracks and dislocations. In addition, surfaces that are not coated with a suitable passivation layer, such as the cut or fracture site, also cause substantial recombination of electrons and holes, leading to a reduction in solar cell performance. Consequently, it is important that most of the surface of the sliver is passivated using a dielectric coating, a diffused layer and/or other means in order to reduce the extent of electron-hole recombination.

Another reason to minimise the cross-sectional area of the silicon bridges is to facilitate the removal of the bridges near the end of processing. Fracturing the bridges is cheaper than scribing the bridges. The smaller the cross-sectional area of the silicon bridges, the less damage will be caused by fracturing, and the lower the probability of accidentally fracturing a sliver.

Not only is it important that the cross-sectional area of silicon bridges be kept to a minimum, but also that the number of discrete silicon bridges be minimised. The reason for this is that the total electron-hole recombination in a solar cell is usually smaller if there are a few large regions of surface damage rather than a multitude of small regions with the same total surface area.

There is a similar need to minimise crystal damage and recombination at the ends of each sliver when they are broken out or cut out of the wafer frame 108 near the end of solar cell processing. The amount of silicon to be fractured or cut is preferably as small as possible while maintaining adequate wafer strength.

The silicon bridges described above can effectively be applied only to one surface of a wafer. They must be applied on the reverse surface from which slot formation will proceed. Otherwise, a continuous slot will not be created, and the silicon bridges will remain throughout the full thickness of the wafer and consequently will have a large cross-sectional area with deleterious consequences as described above. On the one hand, if a laser or dicing saw is to be used for slot formation, then the bridges will make it difficult or impossible to form continuous slots. On the other hand, if selective etching is used for slot formation, then undercutting of the bridges to reduce their cross-sectional area is only possible under special circumstances, as described below.

It is desired, therefore, to provide a method for processing elongate substrates and a substrate securing apparatus that alleviate one or more of the above difficulties, or at least a useful alternative.

### SUMMARY OF THE INVENTION

In accordance with the present invention, there is provided a method for processing elongate substrates, including:
applying securing means to a semiconductor wafer to engage portions of at least one of the opposite surfaces of said wafer; and
forming a plurality of parallel elongate openings through said wafer to form a corresponding plurality of elongate substrates between said openings, each of said elongate substrates having opposite edges coplanar with the opposite surfaces of said wafer, and opposite faces orthogonal to said wafer surfaces;
whereby the engaged portions of said wafer include edges of said elongate substrates, the engagement of said edges inhibiting relative movement of said elongate substrates.

The present invention also provides a method for processing elongate substrates, including:
forming a plurality of parallel elongate openings through a semiconductor wafer to form a corresponding plurality of elongate substrates between said openings, each of said elongate substrates having opposite edges coplanar with opposite surfaces of said wafer, opposite faces orthogonal to said wafer surfaces, and opposite ends by which the elongate substrates are interconnected; and
applying securing means to at least one of the opposite edges of each elongate substrate to engage said edges and thereby inhibit relative movement of said elongate substrates.

The present invention also provides a method for processing elongate substrates, including:
forming a plurality of parallel elongate openings through a semiconductor wafer to form a corresponding plurality of elongate substrates between said openings, each of said elongate substrates having opposite edges coplanar with opposite surfaces of said wafer, opposite faces orthogonal to said wafer surfaces, and opposite ends by which the elongate substrates are interconnected; and
applying a securing apparatus having mutually spaced projections to said elongate substrates so that the projections are disposed between opposing faces of adjacent elongate substrates to prevent adjacent ones of said elongate substrates from touching one another.

The present invention also provides an apparatus for securing elongate substrates, the apparatus including one or more securing members for engaging edges of a plurality of mutually spaced elongate substrates formed in a semiconductor wafer, each of the securing members having mutually spaced locating features for interposing between respective mutually spaced edges of said elongate substrates to inhibit relative movement of said elongate substrates.

The present invention also provides an apparatus for securing elongate substrates, including a plurality of mutually spaced projections for interposing between opposing faces of adjacent elongate substrates to prevent adjacent ones of said elongate substrates from touching one another, the elongate substrates being formed in a semiconductor wafer, each of said elongate substrates having opposite edges coplanar with opposite surfaces of said wafer, opposite faces orthogonal to said wafer surfaces, and opposite ends by which the elongate substrates are interconnected.

The present invention also provides a method for processing elongate substrates, including forming at least three sets of elongate substrates in a circular wafer, each of said sets including a plurality of elongate substrates of equal length, said sets including a first set located about a central region of said wafer, and at least two other sets disposed about said first set, each of the at least two other sets including a plurality of elongate substrates having a length substantially less than the diameter of said wafer.

The present invention also provides a method for processing elongate substrates, including forming three sets of elongate substrates in a circular wafer, two of the three sets including a plurality of parallel elongate substrates of equal length, the third set including a plurality of parallel elongate substrates of equal length and being oriented at an angle of 70.52° to the other elongate substrates, wherein said sets of elongate substrates occupy substantially more than 63% of said wafer.

### BRIEF DESCRIPTION OF THE DRAWINGS

Preferred embodiments of the present invention are hereinafter described, by way of example only, with reference to the accompanying drawings, wherein:

FIG. 1 is a schematic perspective view of a set of elongate substrates retained within a wafer frame, a quarter of which has been removed in order to view half of the elongate substrates;

FIG. 2 is a schematic cross-sectional side view of the retained elongate substrates, illustrating their relative movement;

FIG. 3 is a schematic plan view of a portion of the retained substrates, illustrating the sticking of adjacent substrates to one another;

FIGS. 4 and 5 are schematic cross-sectional side views illustrating the application of securing means to one or both edges of each elongate substrate to reduce their relative movement in accordance with preferred embodiments of the invention;

FIG. 6 is a schematic plan view of a wafer incorporating elongate substrates whose edges are engaged by a planar layer or sheet in accordance with a first preferred embodiment of the invention;

FIG. 7 is a schematic plan view of elongate substrates whose edges are engaged by elongate securing strips orthogonal to the elongate substrates, in accordance with a second preferred embodiment of the invention;

FIG. 8 is a schematic cross-sectional side view of elongate substrates whose edges are engaged by elongate securing strips parallel to the elongate substrates, in accordance with an third preferred embodiment of the invention;

FIG. 9 is a plan view of a wafer including elongate substrates whose edges are engaged by a securing assembly including elongate securing strips orthogonal to the elongate substrates and stabilising crossbeams, in accordance with another preferred embodiment of the invention;

FIGS. 10 and 11 are schematic cross-sectional side views of elongate substrates whose edges are engaged by clamps orthogonal to the substrates in accordance with yet another preferred embodiment of the invention;

FIG. 12 is a plan view of a silicon wafer to which a masking layer has been applied having openings to expose the underlying silicon in accordance with a standard process of the prior art;

FIG. 13 is a plan view of a silicon wafer to which a masking layer has been applied having linear arrays of openings to expose the underlying silicon in accordance with a preferred embodiment of the invention;

FIGS. 14 and 15 are schematic plan views of different arrangements of openings that are used to form stitches spanning slots etched in the wafer by anisotropic wet chemical etching;

FIG. 16 is a schematic plan view of stitches on a (110) oriented silicon wafer illustrating the requirement to incline the stitches relative to the slots;

FIG. 17 is a schematic illustration of a ‘box section’ of elongate substrates whose edges are secured by elongate securing strips or securing members;

FIG. 18 is a schematic illustration of a ‘box section’ of elongate substrates whose edges are secured by an elongate securing strip or securing member and a securing layer or sheet;

FIG. 19 is a schematic illustration of a ‘box section’ of elongate substrates whose edges are secured by an elongate securing strip and securing stitches;

FIG. 20 is a schematic plan view of a wafer in which three sets of elongate substrates have been formed to increase utilisation of the wafer to about 78%; and

FIG. 21 is a schematic plan view of a wafer in which three rhomboidal groups of elongate substrates have been formed to increase utilisation of the wafer to about 82%.

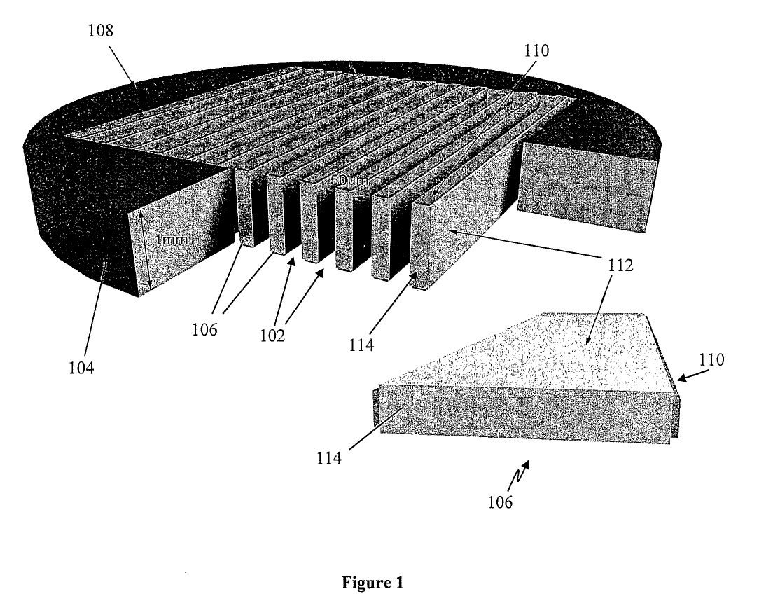

### DETAILED DESCRIPTION OF THE PREFERRED EMBODIMENTS

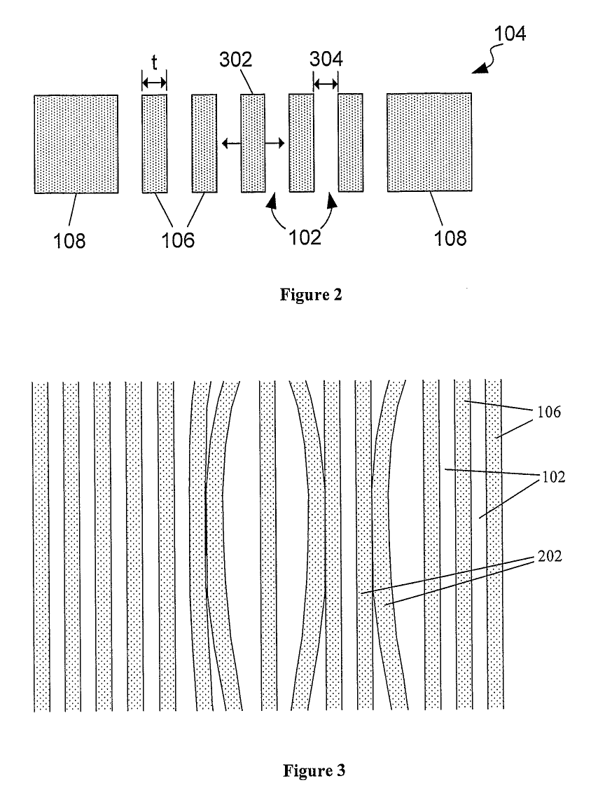

FIG. 2 is a schematic cross-sectional side view through a wafer in which a set of elongate substrates or slivers have been formed by a process such as that described in the sliver patent application. As described above, because each substrate is many times longer than its thickness t, and only the two opposing ends of each substrate are constrained by their attachment to the wafer frame 108, each substrate can to some extent move laterally, as indicated by the arrows in FIG. 3, with the central portion of each substrate farthest away from the opposing ends having the greatest displacement. Bearing in mind that the lateral spacing 304 between adjacent substrates is typically of the order of only 10-50 microns, the physical dimensions of each substrate, in conjunction with the material properties of the material (usually silicon) of which the substrates are composed, allow adjacent substrates to flex and contact one another, which is highly undesirable for the reasons described above.

### Detachable Clamps

This lateral movement can be reduced and adjacent substrates can be prevented from touching one another by engaging the substrate edges with a securing apparatus, clamping tool or clamp having one or more detachable securing members 1002.

The one or more securing members 1002 are preferably of elongate form and are applied in a direction that is substantially orthogonal to the longitudinal axes of the elongate substrates, as shown, and can be applied to one or both surfaces.

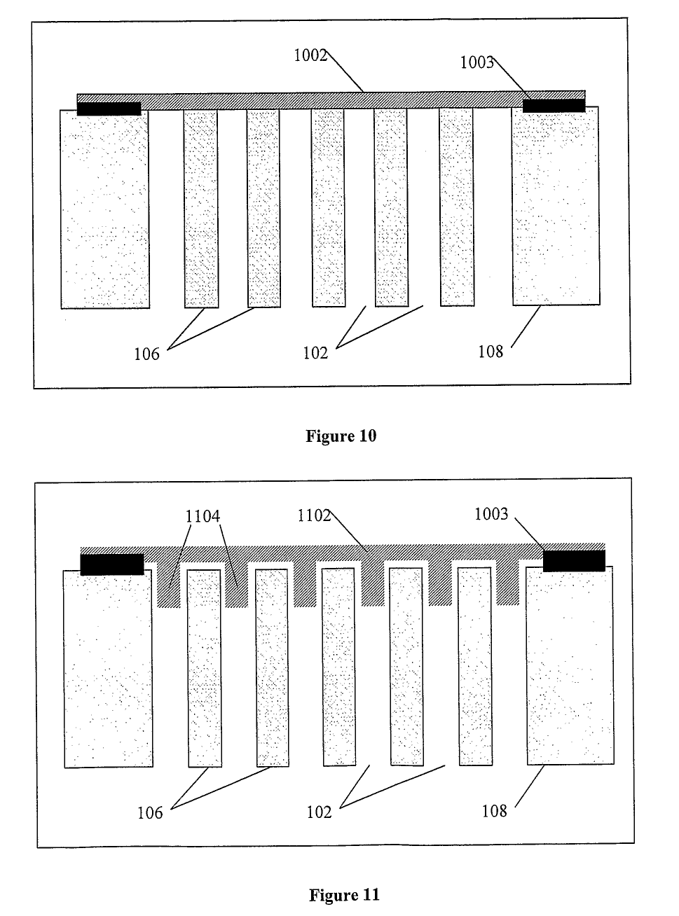

In one embodiment, as shown in FIG. 10, the securing members 1002 engage the edges of the substrates by the application of pressure, and thereby substantially prevent them from bending and touching one another. The securing members 1002 have compliant surfaces so that the substrates are not damaged, but are nevertheless securely held in position. To ensure even spacing between the substrates, it is preferred that the surfaces of the securing members 1002 have periodic indentations whose spacing corresponds to the desired spacing between substrates so that the substrates are secured within respective indentations.

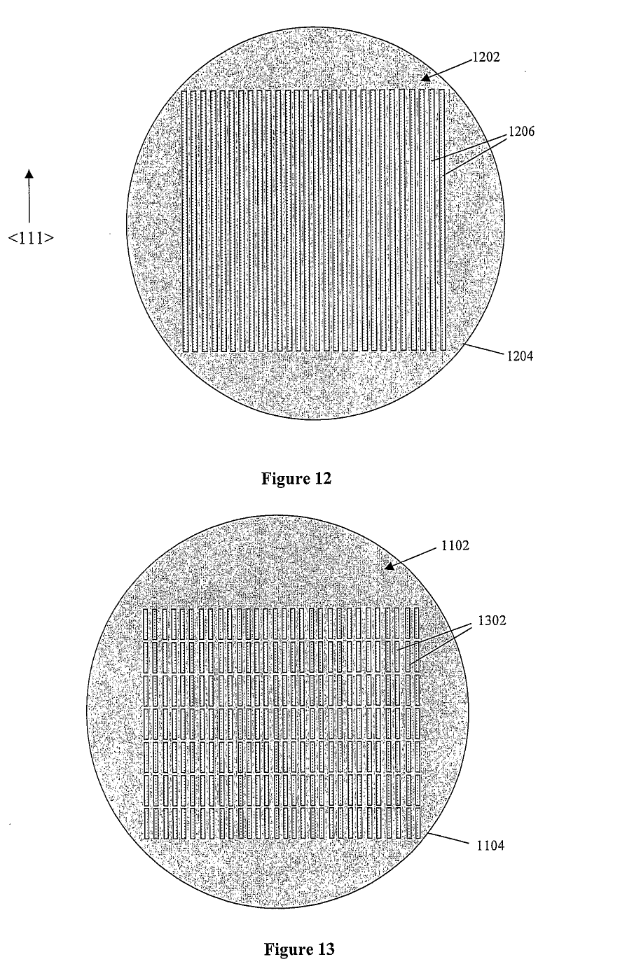

In an alternative embodiment, as shown in FIG. 11, the securing members 1002 include substantially rigid or flexible comb-like projections 1104 that pass into the openings between substrates and thereby prevent them from sticking to one another. The projections 1104 can be smaller than the spacings between adjacent substrates to allow a degree of lateral movement.

In either embodiment, the securing members 1002 can be applied to the substrate edges at any convenient time, including prior to formation of the slots, near the end of the slot formation step, or after slot formation. The securing members 1002 can be applied and removed several times during processing, if desired.

The securing members 1002 can be secured to the wafer near the wafer edges 1003, using mechanical fasteners or by bonding. Alternatively, securing members 1002 on opposite surfaces of the wafer can be joined together, by a hinged or resilient portion (not shown).

The clamping tool can be removed from the substrates by unfastening the mechanical fasteners or by unbonding or scribing off the bonding regions.

The clamping process is facilitated by the flatness of the surface of the wafer. The securing members 1002 that rely on pressure to hold the substrates in place are preferably resilient or flexible, as this allows them to conform to the surface of the host wafer and thus to engage most or all of the substrate edges.

Preferably, the clamps are coated with or fabricated from one or more materials that are compatible with one or more semiconductor processing steps to which the substrates are subsequently subjected, such as washing, etching, metal and dielectric depositions, oxidations and/or diffusions. Suitable materials are those that would not be substantially adversely affected by these processes, and would not adversely change the nature of the process or contaminate the silicon material.

To ensure compatibility with such process steps, two or more different clamps coated with or manufactured from respective materials can be used at different stages of the semiconductor processing to which those materials are suited. For example, clamps used in wet chemical solutions can be manufactured from Teflon, polypropylene, polyethylene or other suitable and chemically resistant materials. Clamps for use at high temperature can be manufactured from silicon, silicon dioxide, silicon nitride, silicon carbide or other materials with high melting points and suitably low impurity concentrations.

### Bonding Strips and Bonding Sheets

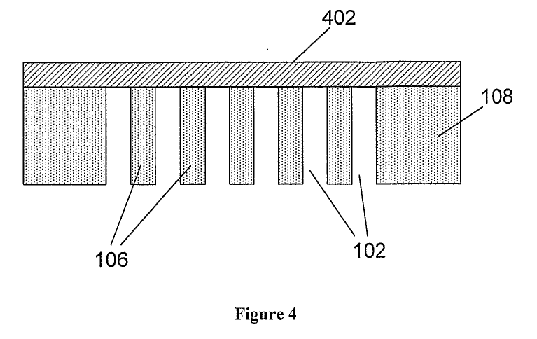

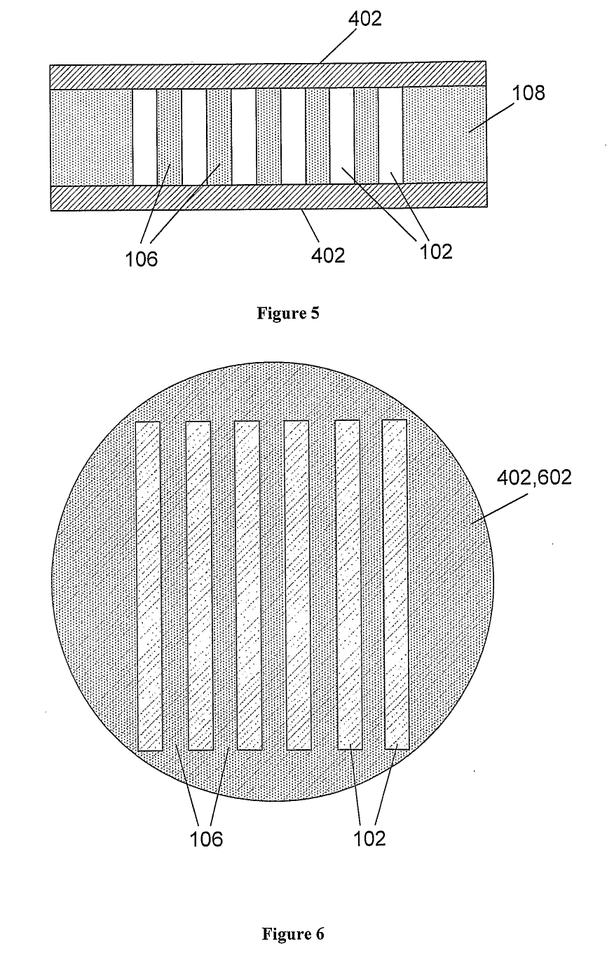

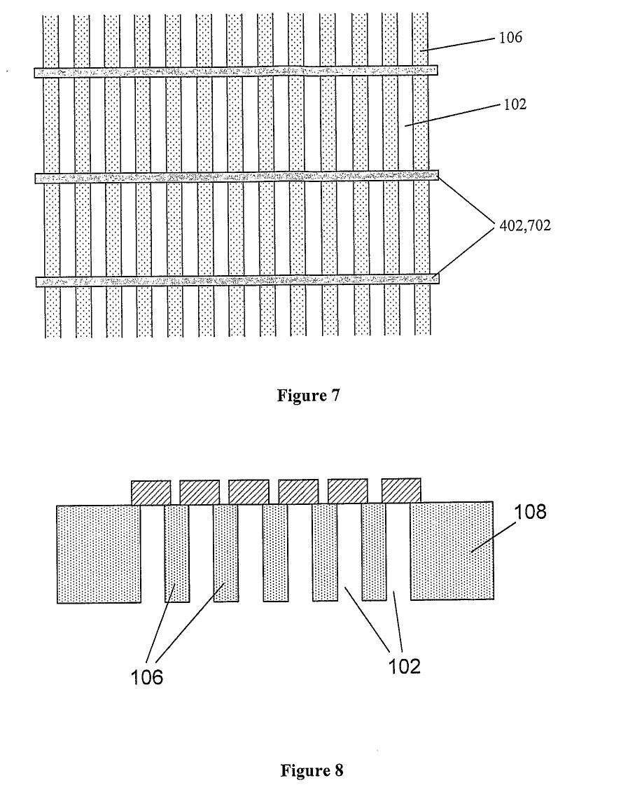

In an alternative embodiment, as shown in FIGS. 4 and 5, the amount of substrate movement is reduced by applying a securing or stabilising material or layer 402 onto at least one of the two surfaces of the wafer 104, preferably by a bonding process as described below. As shown in plan view in FIG. 6, the layer 402 can be in the form of a planar sheet 602, or alternatively can be in the form of one or more elongate strips 702, as shown in FIG. 7. The strips 702 can be previously formed and then applied to the substrate edges, or alternatively can be formed by removing portions from one or more planar sheets 602. The strips and sheets can have a wide range of thicknesses consistent with ease of handling and survivability through processing, and preferably have a thickness of about 10 to 300 micrometres.

The securing strips 702 can be applied to the wafer 102 to be substantially orthogonal to the length of the substrates, as shown in FIG. 7, or alternatively, can be inclined at some other angle to the substrates, or can even be oriented substantially parallel to the length of the substrates. If the strips 702 are exactly parallel to the longitudinal axes of the substrates, then each of the many bonded strips is sufficiently wide to span the gap 102 between adjacent substrates, as shown in cross-section in FIG. 8. The securing properties of this latter arrangement can approach that of the continuous bonding sheet 602.

In any case, the material 402 applied to one or both of the opposing edges of each substrate secures the substrates by constraining them from subsequent relative lateral movement in order to maintain a substantially constant spacing between adjacent substrates and in particular to substantially prevent adjacent substrates from touching one another.

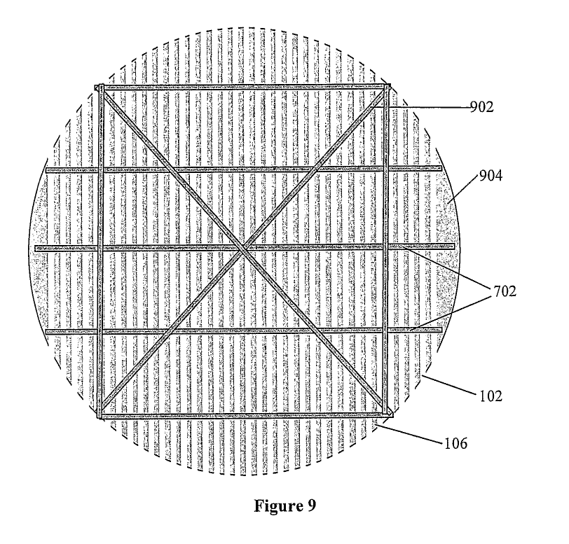

Alternatively, as shown in FIG. 9, an array of securing strips 702 can be joined by multiple crossbeam strips 902 to form a securing assembly of improved structural integrity and to assist in handling the securing strips 702 (which can thus be handled as an integral unit) prior to their application to the substrates.

Although the securing material 402 can be applied to the edges of the substrates using a variety of methods, including various forms of deposition, it is preferred that the securing material 402 is attached to the substrate edges by a bonding process. The securing material 402 can be bonded to the substrate edges at any convenient time in the solar cell fabrication process, including prior to formation of the slots, near the end of slot formation, or even after slot formation is complete (although, depending on how this bonding is performed, this may allow the possibility of non-uniform spacing between substrates, and the risk that at least some of the substrates may have already contacted or stuck to one another).

The securing material 402 is preferably silicon, quartz, borosilicate glass or silicon carbide. However, it will be apparent to those skilled in the art that a wide variety of alternative materials can be used, providing that they can be suitably bonded to the substrate edges, and that they are compatible with the subsequent processing steps used to process the substrates. Alternatively, the securing material 402 can include a coating layer of a material such as silicon dioxide or silicon nitride. In any case, the materials used are chosen for their compatibility with wet chemical steps such as washing and etching and or vacuum processes and/or high temperature process steps such as dielectric depositions, oxidations and/or diffusions. Suitable materials are those that would not be substantially adversely affected by these processes, and would not adversely change the nature of the process or adversely contaminate the substrates. In addition, any thermal expansion mismatch should be taken into account in order to avoid excessive stress on the substrates to whose edges they are bonded caused by changes in temperature.

The securing material 402 is preferably bonded to the edges of the substrates using glue, eutectic bonding and/or chemical bonding, as described in Silicon Wafer Bonding Technology, edited by S. S. Iyer and A. J. Auberton-Herve, publisher INSPEC, ISBN 0852960395 (“Iyer”). The bonding processes described in Iyer give rise to bonds that are compatible with most standard semiconductor processes, including etching, washing, oxidation, deposition and diffusions. Wafer bonding technology can also be used to bond foreign materials to silicon and other semiconductors, provided that adequate measures for stress relief are included, particularly if the bonding technique is performed at an elevated temperature, or if high temperature processes follow. In any case, the bonding method uses materials that are compatible with any subsequent processing steps, as described above.

The bonding process is assisted by the flatness of the surface of the host wafer. Additionally, if the bonding material (i.e., strips and/or sheet) 402 is sufficiently thin to be flexible, this will help the material 402 conform to the surface of the host wafer and successfully bond to most or all of the substrate edges.

Removal of the bonding strips or sheets can be accomplished with a laser or by mechanical fracturing or etching of the material that bonds the strips or sheets to the substrate edges or a combination of the foregoing. Fracturing can be accomplished by bending the wafer about an axis that is parallel to the long axis of the substrates in order to put stress on the securing strips or sheets or on their bond with the substrate edges. Alternatively, substrates can be removed one at a time by rotating each substrate in turn about its long axis, thus placing stress on the securing strips or sheets or on their bond with the substrate edge.

If the substrate edges to which the securing strips 702 or sheet 602 adhere are coated with a material such as a dielectric prior to bonding, then there will be no electrical continuity between the substrates (or, if the bonding is performed prior to substrate formation, the portions of the silicon wafer that will later constitute substrates) and the bonding strips 702 or sheets 602. This allows the fracture or removal of the bonding material 402 at a later stage in the manufacturing process without causing electrical disturbance, such as a substantial increase in electron-hole recombination.

### Stabilising Membranes

In yet a further embodiment, rather than applying the bonding securing material 402 to the substrates by bonding, the securing material can be grown or deposited on the substrates prior to, or soon after, commencement of the process of forming slots between the substrates. In this embodiment, the securing material is in the form of a very thin layer, typically 0.1 to 2 microns thick, which is therefore referred to as a membrane. The membrane is preferably composed of a dielectric material such as silicon dioxide or silicon nitride that is grown or deposited prior to slot formation.

In order to allow the formation of slots between the substrates, a continuous membrane cannot be applied to both surfaces of a wafer. Moreover, special conditions are required of a discontinuous membrane if it is to be successfully used in conjunction with anisotropic etching of (110) silicon substrates, as described below.

The membrane material and thickness are selected to provide sufficient strength, either alone or in combination with other securing methods described herein, to substantially prevent substrate movement as described above. The membrane can be continuous or discontinuous. If a membrane is discontinuous, then the parts of the membrane that connect substrates to neighbouring substrates are referred to herein as “stitches”.

In one embodiment, a relatively thick (0.2 to 2 micrometres) membrane is grown or deposited on one or both surfaces of the wafer 104 prior to formation of the slots. Using standard lithography, openings are made in the membrane formed on one wafer surface to expose the underlying silicon and thereby allow the etching of slots through the wafer. The thickness of the membrane is selected to be sufficiently large to survive the slot etching process and retain sufficient strength at the end of the process to stabilise the substrates. Etching of the wafer is terminated when the slots reach the membrane on the opposite surface. If desired, the etching process can be modified when it is nearly complete in order to reduce its vigour and thereby reduce its effect on the membrane on the opposite wafer surface (if present). Thus one of the edges of each substrate is secured by the continuous membrane.

In another alternative embodiment, the membrane has at least two thicknesses in respective regions, achieved for example by selective deposition of a dielectric material such as SiN on a continuous base layer of silicon dioxide. The thickness and composition of these regions are selected so that the thinner regions of the dielectric membrane are removed by the silicon etching process, leaving a discontinuous membrane in the originally thicker regions. Alternatively, the continuous layer can be omitted entirely and the discontinuous layer defined in one step by selective deposition, for example by using shadow masking of an evaporated material.

Additionally, a layer of aluminium or other metal can be deposited to reinforce the dielectric membrane if desired. Some anisotropic etches such as tetramethyl ammonium hydroxide (TMAH) do not etch aluminium under certain etch conditions. If aluminium is used, then the anisotropic etching of the silicon wafer is performed using TMAH under these conditions. Alternatively, the deposited metal layer can be encapsulated between dielectric layers such as silicon dioxide and/or silicon nitride in order to prevent etching of the metal layer during slot formation.

### Discontinuous Membranes Created by Anisotropic Etching

In yet a further embodiment, a discontinuous membrane can be formed that spans only a portion of each slot opening by exploiting the crystal properties of the silicon wafer.

As described above and in the Sliver patent application, deep, long and narrow slots or trenches with (111)-oriented sidewalls can be fabricated in (110)-oriented silicon wafers by wet anisotropic chemical etching using etchants such as potassium hydroxide (KOH) or tetramethyl ammonium hydroxide (TMAH). These slots can extend all the way through the silicon wafer to create separate substrates. For a (110) wafer (with the [1 1 0] direction perpendicular to the wafer surface), the two vertical {111} planes are (−1 1 −1) and (1 −1 −1), which intersect the wafer surface along the [1 −1 −2] and [−1 1 −2] directions respectively.

As described in the sliver patent application and shown in FIG. 12, the slots can be formed by growing or depositing a masking layer of silicon dioxide or silicon nitride or similar material 1202 on both surfaces of a (110) oriented wafer 1204 and patterning one of the resulting silicon dioxide layers using standard photolithographic techniques in order to form a one-dimensional array of elongate openings or “windows” 1206 in the oxide masking layer 1202 on one wafer surface to expose the underlying silicon. It should be appreciated that the representation in FIG. 12 is schematic in nature; in reality the windows 1206 are typically only 10-50 micrometres wide, spaced 40-100 micrometres apart and have a length of up to 90% of the wafer diameter. The longitudinal axis of the windows 1206 is aligned with the [1 −1 −2] or [−1 1 −2] crystallographic directions of the (110) wafer. The masking layer on the reverse surface of the wafer 1204 is protected during the patterning of the silicon dioxide. The entire wafer is then immersed in an anisotropic etchant such as KOH. KOH etches (110)-oriented silicon more than 100 times faster than (111)-oriented silicon. Due to the orientation of the long axis of the windows 1206 about the surface normal of the wafer 1204, vertical trenches or slots form with slow-etching (111)-oriented sidewalls. Etching continues until the slots extend completely through the wafer. It will be appreciated that other materials can be used as the etch mask and that other anisotropic etchants can be used.

However, in a further embodiment, discontinuous membranes can be prepared in the form of membrane “stitches” that span the slots for part but not all of their length to secure the substrates and yet allow access of the etchant to the underlying silicon.

There are several reasons that make it desirable to form stitches on one surface of the wafer and a continuous membrane on the reverse surface, or stitches on both surfaces. In particular, these arrangements stabilise both edges of the substrates. Moreover, by aligning etching windows on opposite surfaces of the wafer, continuous slots extending completely through the wafer can be formed by immersing the wafer in an etching solution for a period of time sufficient to etch only a little more than half the thickness of the wafer from each direction. This reduces the widening of the slots during etching caused by the relatively slow etching of the sidewalls and thus allows the production of more substrates from each wafer. Alternatively, for a given final slot width it allows the wafer to be twice as thick.

It will be apparent that account must be taken of the crystallographic-orientation-dependent etching process, since the presence of slow-etching (111) planes can cause delayed or even incomplete etching of the silicon in the slots. Consequently, the discontinuous layer is formed as follows.

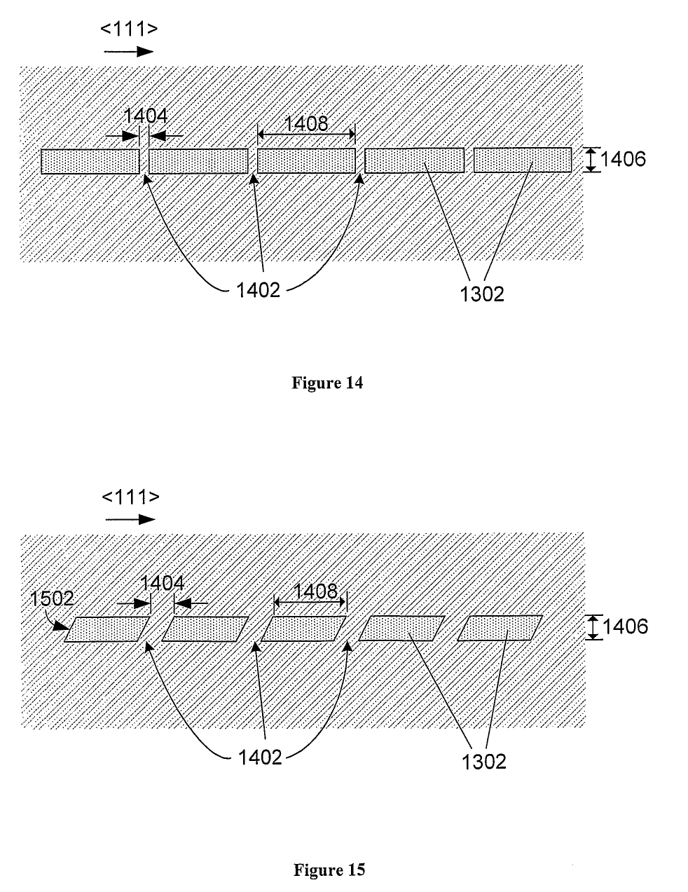

First, rather than forming the set of elongate openings in the oxide masking layer as described above as shown in FIG. 12, each elongate opening is replaced with a linear array or row of shorter openings 1302, visually resembling a parallel set of dashed lines or lines of sewing stitches, as shown in FIG. 13. For clarity of explanation, the process is described below with reference to a single one of the linear arrays or rows of window openings 1302 (i.e., a single dashed line or line of stitches), as shown in FIG. 14, where the regions 1402 of membrane separating the windows 1302 are referred to as stitches 1402. However, it should be understood that in practice many such linear arrays extending across the wafer will be used, as shown schematically in FIG. 13. In practice, the number of oxide stitches 1402 is preferably approximately equal to the number of slots.

Upon immersion of the wafer in KOH, etching proceeds in the (110) direction normal to the wafer surface, uncovering (111)-oriented sidewalls as described above. Ideally, the silicon would be etched approximately uniformly through the full thickness of the wafer and undercut the oxide stitches 1402 to form a continuous slot spanned by the oxide stitches 1402, being the regions 1402 of oxide separating each window 1302 as described above.

However, due to the arrangement of windows 1302, in practice undesired (111) planes are uncovered, and these can prevent complete removal of the silicon beneath the oxide stitches 1402. For many arrangements of windows 1302, continuous slots extending through the full thickness of the wafer will not be formed. However, this can be avoided as follows.

A (110) silicon wafer includes vertical sets of (111) planes separated by an angle of 70.5 degrees. In the lithographic process step used to define the dimensions and orientation of the windows 1302 relative to the wafer, the latter is selected so that one set of (111) planes (“Set 1”) is parallel to the longitudinal axis of the etched slots and will form the sidewalls of the slots. At the end of each mask window 1302, the second set of (111) planes (“Set 2”) will be exposed to form a second set of walls bounding each trench as the etching proceeds. Consequently, if the gap 1404 between the ends of adjacent slots is too large, then the Set 2 planes will prevent the individual slots from joining together (by undercutting the masking layer) to create a single continuous slot extending beneath the oxide stitches 1402.

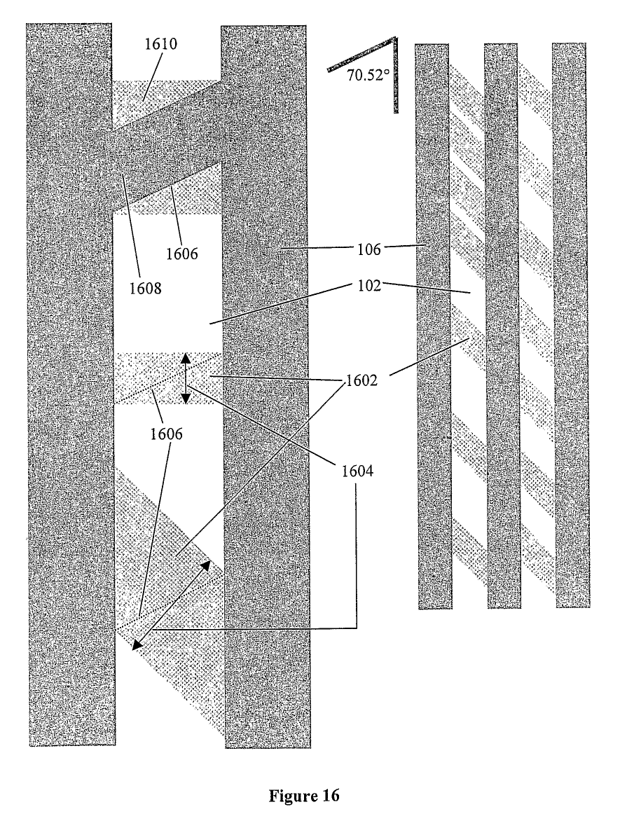

As shown in FIG. 16, membrane stitches 1602 can be oriented at arbitrary angles with respect to the longitudinal axes of the slots 102 between substrates 106. However, for crystallographic reasons, some angles allow wider 1604 and stronger stitches to be used while still creating continuous slots. Stitches 1602 can be spaced apart widely (as shown in the left-hand side of FIG. 16) or narrowly (as shown in the right-hand side of FIG. 16) compared with their width 1604. However, narrow spacing confers greater strength to the stitches and better resistance to movement of the substrates.

As described above, a first set of (111) planes defines the sidewalls of each slot 102. However, there is an additional set of vertical (111) planes that make an angle of 70.5 degrees with the (111) planes of the slot sidewalls, as represented by diagonal lines 1606 in FIG. 16. Due to their relative slow etching rate, these additional vertical (111) planes can prevent the creation of a continuous slot, leaving individual trenches bounded at each end by residual (111) sidewalls 1608. As shown in the left-hand side of FIG. 16, an overhanging dielectric membrane 1610 will be created but will not be completely undercut.

Consequently, it is important to ensure that the gap 1404 between the adjacent ends of adjacent mask windows or openings 1302 is sufficiently small and that the ends of the mask windows 1302 have an appropriate shape, as described below. The gap 1404 between the ends of adjacent windows 1302 is preferably about equal to the width 1406 of the window 1302, as described below.

In particular, if the window ends are orthogonal to the (111) direction (as they will be if the window is rectangular, as shown in FIG. 14), then the distance 1404 between the adjacent ends of adjacent windows (the maximum width 1404 of the oxide stitch 1402) is selected to be less than 35% of the width 1406 of the etched slots in order to guarantee the formation of a continuous slot. The silicon beneath the oxide stitches 1402 will then be able to be completely etched.

Alternatively, if the window ends 1502 form an angle of 19.5 degrees with the longitudinal axis of the window 1302, as shown in FIG. 15, then the maximum length 1404 (i.e., the dimension parallel to the longitudinal axes of the slots) of the oxide stitch 1402 is selected to be less than 106% of the width 1406 of the slots in order to form a continuous slot. The stitch 1402 will be inclined with respect to the long axis of the slots. Angles between 90 and 19.5 degrees have maximum widths for the oxide stitches in the range of 35% to 106% of the slot width. These percentage figures are derived from the geometry of the (111) planes in (110) oriented wafers.

To increase the stabilisation of substrates, the spacing 1408 between oxide stitches 1402 (i.e., the length 1408 of each mask window 1302) can be as small as desired, subject to the constraint that it is large enough to allow sufficient interchange of process chemicals. For example, stitches can cover at least 80-90% of each slot while still allowing for complete slot etching, and this arrangement is nearly as effective for securing the substrates as a continuous membrane.

### Stabilising Both Edges of Each Substrate

In general, the methods described above can be used to secure either one or both edges of each substrate. However, stabilisation of both edges of each substrate suppresses substrate movement more effectively than stabilisation of only one edge. In particular, securement of both edges of each substrate allows the wafer frame 108 to be completely removed and yet the substrates remain in a mutually spaced arrangement and can be handled and processed as a single integral unit. If only one edge of each substrate is secured, the array of substrates is unstable against even slight compressive stress in a direction orthogonal to the faces of the substrates.

Notwithstanding the above, the presence of a narrow wafer frame 108 is convenient for handling and forming substrates. For example, a 1 mm wide annular frame will occupy only about 2.5% of a 150 mm diameter wafer and confers the advantages of firmly holding both ends of each substrate in place, reducing the chance of accidental breakage by catching the loose end of a substrate during wafer handling and largely eliminating the requirement for bracing or box sections as described below.

However, retention of a wafer frame has an important disadvantage. Removal of the wafer frame and allowing slots to intersect the wafer edge avoids having to break out the substrate ends from the wafer frame, which leads to damage to silicon and a reduction in solar cell efficiency, as described above.

The bonding strips and sheets, clamps, membranes, and stitches described herein can be used to stabilise both edges of each substrate. Stabilisation of both edges of the substrates reduces twisting moments on the substrates and places less stress on the bonding strips and sheets, clamps, membranes and/or stiches used to secure them. However, it will usually be necessary to partially etch the slots before applying bonding strips or clamps if the slots are formed by anisotropic etching to ensure that the etchant has access to the region immediately beneath the bonding strips or clamps so that a continuous slot can be created.

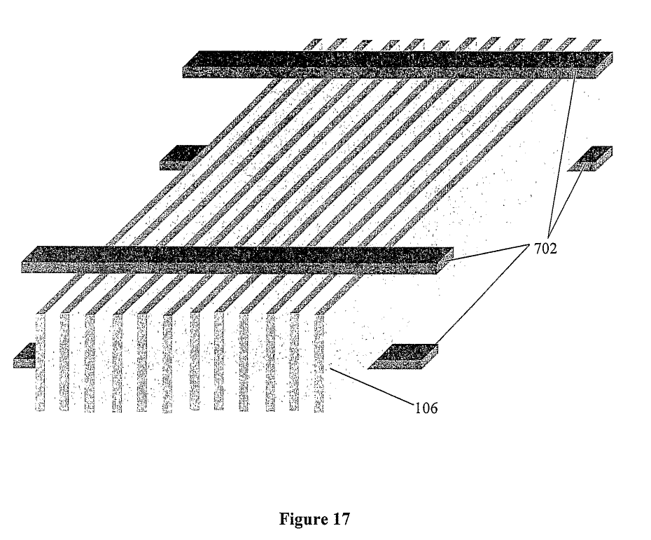

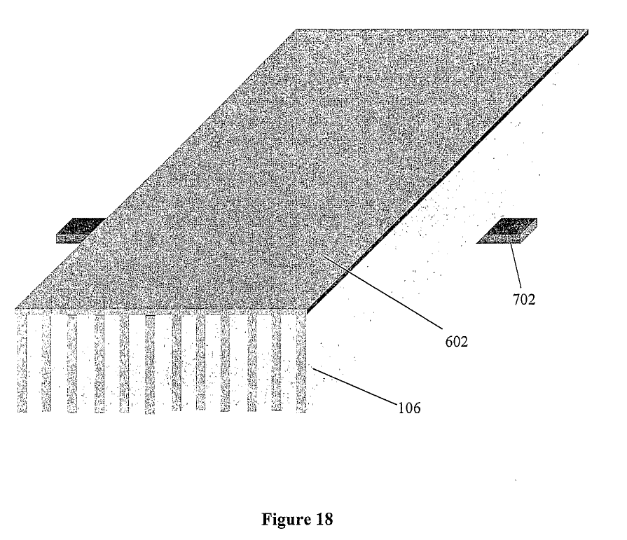

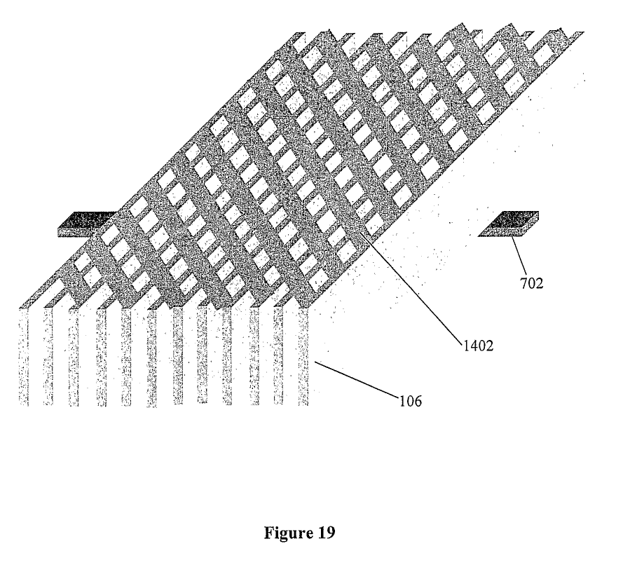

For example, FIG. 17 shows how bonding strips 301 can be applied to both edges of an array of substrates 102 to create a ‘box section’ that is structurally rigid, and allows the substrate to be more easily handled during processing in the absence of a wafer frame 108. FIG. 18 shows an alternative arrangement whereby bonding strips 301 are applied to the edges of an array of substrates 102 and a bonding sheet 401 is applied to the opposite edges. Alternatively, continuous detachable clamps or membranes can be used. FIG. 11 shows another alternative arrangement whereby bonding strips 301 are applied to the edges of an array of substrates 102, and membrane stitches 701 are applied to the opposite edges. It will be apparent that a wide variety of combinations are possible.

### Further Advantages

The securing strips and sheets, clamps, membranes and stiches described herein provide several further advantages over the prior art. If discontinuous rather than continuous bonding strips, clamps and stitches are used to hold the substrates in place then there is reduced interruption of the free flow of process solutions and gasses. However, if continuous bonding sheets, clamps and membranes are used, then the blocking of process solutions or gasses from one side can be used to advantage. For example, additional protective measures to avoid unwanted diffusions or chemical etching are unnecessary in the regions to which the securing means are applied. In the case of continuous bonding sheets, clamps and membranes, one entire surface of the host wafer is fully protected. This assists with process flexibility and allows for novel device designs.

Additionally, the protected regions can be used as masks to perform selective deposition of materials onto the substrates or etching of materials, whereby the deposition or etching occurs only on regions that are not obscured by securing strips, sheets, clamps, membranes, and/or stitches. These securing means can also be used to selectively shade parts of the substrates when using directional processes such as vacuum evaporation, ion implantation and reactive ion etching. Novel devices can be produced using such techniques.

Advantageously, the securing means, whether in the form of bonding strips, sheets, membranes or stitches, can be thin (around 0.5-50 micrometres) and yet still provide sufficient tensile and compressive strength in a plane parallel to the surfaces of the wafer for the purpose of holding the substrates in place. Moreover, if the securing means are sufficiently thin, it is easy to fracture them when the substrates are removed from the wafer near the end of the process, thus avoiding the need for more expensive measures such as laser scribing to separate individual substrates. For example, one method of applying an appropriate force is to establish a vibration in the substrates by stroking them in a direction orthogonal to their faces with a soft tool that does not damage the substrates by scratching any of the protective layers applied to the substrate.

Alternatively, a relatively small number of bonding strips can be used so that it is feasible to break them to allow extraction of the individual substrates with the aid of a computer-controlled laser. For example, a Q-switched laser beam in pulse mode can be scanned along each bonding strip, with the Q-switch being activated when the beam is positioned over each slot. In this way the bonding strip can be weakened or destroyed without damaging each substrate.

The fracture or removal of the bonding strips and sheets, clamps, membranes and/or stitches at a late stage in the manufacturing process does not cause electrical disturbance, such as the increase in surface electron-hole recombination rates that is typically caused by fracturing part of the silicon and exposing parts of the surface of the silicon substrate without any damage etching and surface passivation.

In a typical substrate formation process, eventually the ends of the substrates will be cut or fractured to release the substrates from the host wafer, producing substantial local damage. However, if the bonding strips and sheets, clamps, membranes or stitches are left in place during and after the cutting or fracturing of the substrate ends, the substrates can retain their positions relative to one another. This allows the cut ends of the substrates to be subjected to semiconductor processes known to reduce surface recombination rates, such as damage etching, diffusion and oxidation. Moreover, these processes can be integrated with passivation processes used to improve other parts of the substrates.

Relatively short substrate solar cells can be used to generate power in small devices such as consumer electronics including mobile phones, personal digital organisers, toys, watches and other. They can also be used to foam concentrator solar receivers for microconcentrator systems. Short substrates can easily be created by dividing long substrates into multiple short pieces. However, the process of dividing the substrates will usually cause additional recombination at the ends. The shorter the resulting substrate is then the larger will be this additional recombination as a proportion of total cell recombination, and the larger will be the deleterious effect of this additional recombination.

The use of bonding strips and sheets, clamps, membranes and/or stitches as described herein allows the fabrication of short substrate solar cells that do not suffer from substantial electron-hole recombination at their ends. This is accomplished by dividing each substrate into multiple short sections before a surface passivation step during the formation of solar cells on the substrates. The bonding strips and sheets, clamps, membranes or stiches hold each short substrate in place during wafer processing.

### Substrate Patterns

As shown in FIG. 12, substrates are typically formed in a circular wafer as a square pattern of equal-length substrates, or a rectangular pattern that is substantially square. However, the maximum fraction of a circular wafer that can be occupied by a single square or rectangular block of substrates is shown by simple geometry to be 63%.

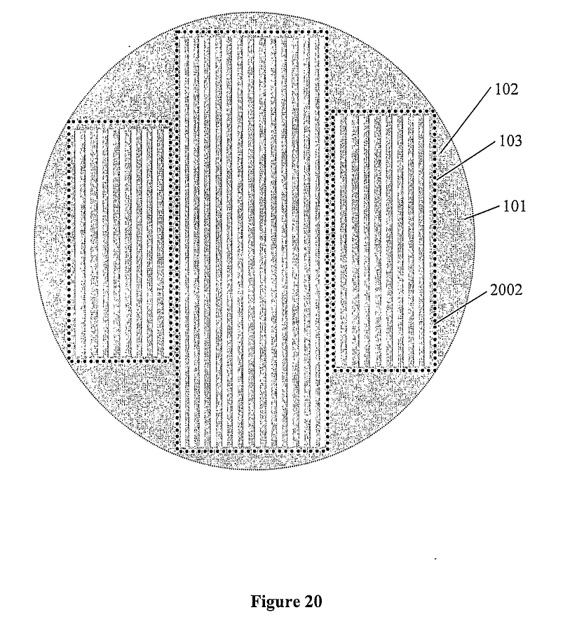

Alternative layouts result in improved utilisation of the host wafer. As shown in FIG. 20, rectangular blocks or sub-arrays of equal-length substrates can be created that confer the advantage of improved wafer utilisation compared with a square pattern. Alternatively, the substrates can run in an orthogonal direction to the long axis of the rectangles to substantially reduce the average substrate length. However, if the substrates run in a direction parallel to the long axis of the rectangles as shown in FIG. 20, then the substrate area will be larger and fewer substrates will need to be handled during device formation.

The wafer utilisation in such an arrangement is found by geometry to be limited to 78% for three rectangular blocks, compared with 64% in the case of a square pattern.

Additionally, the ability to form sub-arrays of substrates during and following detachment from the host wafers allows for substantially easier handling of the substrates from each of the rectangular blocks. Sub-arrays can be readily formed by cutting the wafer around the periphery of each rectangular block, as shown by the dotted lines 2002, while leaving a relatively narrow peripheral frame or interconnecting portion of wafer material so that the elongate substrates within the block remain interconnected together as an integral unit, even after the block of elongate substrates has been otherwise removed from the host wafer. The sub-arrays can be detached from the host wafer by a variety of means including scribing with a laser or dicing saw. Alternatively, if it is desired to avoid the use of an interconnecting frame 2002 in order to avoid cutting the ends of the substrates after the completion of solar cell fabrication, then sub arrays can be defined by cutting through the wafer by etching or with a laser or dicing saw at an earlier stage so that the ends of each elongate substrate are exposed and can therefore be processed to reduce carrier recombination. Bonding strips, sheets, clamps, membranes and/or stiches are used to hold each elongate substrate in place during processing.

Advantage can be taken of the ability to produce substrate sub-arrays to facilitate the handling of substrates of different lengths. Sub-arrays of equal-length substrates can be transported, stored, binned and subjected to characterisation tests. This avoids the need for a machine to handle variable length substrates while arranging the substrates to form working devices.

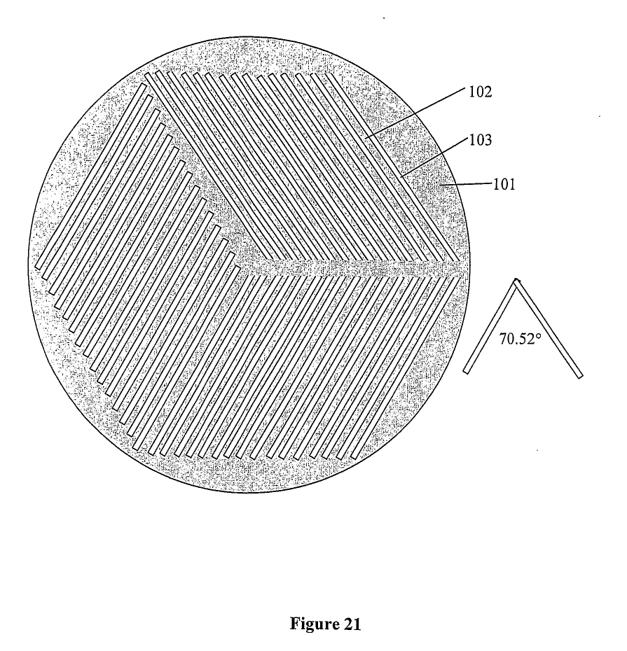

Alternatively, if the slots are created using anisotropic etching of a (110) wafer, then certain constraints apply to the angle between sets of slots. As shown in FIG. 21, three sub-arrays of substrates can be created, each with a substantially rhomboidal shape, two with the substrates parallel to each other and the third with the substrates running at an angle of 70.5 degrees to those in the other two sub-arrays. Since this is close to the 60 degree angle required for three identical rhomboids, little space need to be wasted between the three sub-arrays.

Moreover, the arrangement of three rhomboidal blocks of substrates shown in FIG. 21 forms substrates of equal lengths, facilitating handling of the substrates following removal from the host wafer. Advantageously, the wafer utilisation in such an arrangement is found by simple geometry to be limited to 82%, compared with 63% in the case of a square pattern. The ability to form sub-arrays of substrates during and following detachment from the host wafer allows for substantially easier handling of the substrates from each of the three rhomboidal blocks.

Preferred embodiments of the invention have been described in terms of anisotropic etching of silicon. However, it will be apparent that the methods described herein are generally applicable to other semiconductor materials and to other techniques of slot formation.

Many modifications will be apparent to those skilled in the art without departing from the scope of the present invention as herein described with reference to the accompanying drawings.

1. A method for processing elongate substrates, comprising:
forming a plurality of parallel elongate openings through a semiconductor wafer to form a corresponding plurality of elongate substrates between said openings, each of said elongate substrates having opposite edges coplanar with the opposite surfaces of said wafer, opposite faces orthogonal to said wafer surfaces, and opposite ends by which the elongate substrates are interconnected; and
prior to or after forming the plurality of openings, applying securing means to at least one of the opposite surfaces of said wafer such that after formation of said openings, the securing means engages at least one of said edges of each elongate substrate and thereby inhibit relative movement of said elongate substrates.

2. (canceled)

3. The method of claim 1, wherein the engagement of said edges maintains a substantially constant spacing between said elongate substrates.

4. The method of claim 1, including forming solar cells in the engaged elongate substrates.

5. The method of claim 1, wherein said securing means includes a securing apparatus having one or more securing members that engage said edges.

6. The method of claim 5, wherein each of said one or more securing members includes a resilient surface that presses against said edges.

7. (canceled)

8. The method of claim 5, wherein each of said one or more securing members includes mutually spaced indentations for engaging respective edges of said elongate substrates.

9. The method of claim 5, wherein each of said one or more securing members includes mutually spaced projections that are disposed between opposing faces of adjacent elongate substrates to prevent the elongate substrates from touching one another.

10. The method of claim 5, wherein said securing apparatus includes a plurality of securing members that engage opposite edges of each elongate substrate.

11. The method of claim 1, wherein said step of applying securing means is performed partway through said step of forming said plurality of parallel elongate openings through said semiconductor wafer.

12. The method of claim 5, wherein said securing apparatus is made from one or more materials that are compatible with subsequent processing of said elongate substrates to at least partially form devices in said elongate substrates.

13. The method of claim 5, wherein said securing apparatus is made from one or more materials that are compatible with first processing steps to partially form devices in said elongate substrates; and the process includes replacing said securing apparatus with a second securing apparatus after performing said first processing steps, said second securing apparatus being made from one or more materials that are compatible with second processing steps of said elongate substrates to continue the formation of said devices in said elongate substrates.

14. The method of claim 12, wherein the one or materials include one or more materials selected for compatibility with wet chemical processing.

15. The method of claim 12, wherein the one or materials include one or more materials selected for compatibility with high temperature processing.

16. The method of claim 1, as claimed in wherein said step of applying securing means includes attaching a layer of a securing material that engages said wafer surface.

17. The method of claim 16, wherein said layer of securing material is attached to said wafer surface by an adhesive disposed between said securing material and said wafer surface.

18. The method of claim 16, wherein said layer of securing material is attached to said wafer surface by direct bonding or anodic bonding.

19. The method of claim 16, wherein said layer of securing material engages said edges of said elongate substrates.

20. The method of claim 16, wherein said layer of securing material is attached to said edges by a eutectic bonding process or other metal melting process.

21. The method of claim 1, wherein said step of applying securing means includes growing a layer of a securing material that engages said edges.

22. The method of claim 21, wherein said securing material is grown on one of said opposite surfaces of said water, and said plurality of parallel elongate openings through said wafer is formed from the other of said opposite surfaces of said wafer.

23. The method of claim 21, wherein said step of applying securing means includes growing layers of said securing material that engage respective opposite edges of each elongate substrate.

24. The method of claim 21, wherein said securing material includes a dielectric.

25. The method of claim 21, wherein said securing material includes a metal.

26. The method of claim 16, wherein said layer of securing material is in the form of one or more elongate strips attached to said edges of said elongate substrates.

27. The method of claim 16, wherein said layer of securing material includes a plurality of parallel rows of openings in the securing material to expose respective portions of said semiconductor wafer, said rows of openings being inclined at a selected angle to a selected crystal plane of said semiconductor wafer.

28. The method of claim 27, including forming said plurality of openings in said layer of securing material.

29. The method of claim 27, including anisotropically etching the regions of the semiconductor wafer exposed by each row of openings to form a continuous corresponding one of said parallel elongate openings through said semiconductor wafer, the continuous opening being spanned by portions of said layer of securing material disposed between the openings of the row of openings.

30. The method of claim 29, wherein said step of anisotropically etching includes:
anisotropically etching the regions of the semiconductor wafer exposed by each row of openings to form a corresponding row of trenches, the selected crystal plane of said semiconductor wafer having a relatively low etch rate such that corresponding crystal planes form opposing sidewalls of each of said trenches;
wherein each of said openings in the securing material includes opposite edges inclined at an angle to said planes, said angle and a spacing between adjacent edges of adjacent ones of said openings being such that the trenches in each row join together beneath the portions of said securing material between adjacent openings to form a continuous corresponding one of said parallel elongate openings through said semiconductor wafer, the continuous opening being spanned by said portions of said securing material between said openings.

31. The method of claim 27, wherein layers of said securing material are attached to respective opposite sides of said semiconductor wafer; each of said layers including a plurality of parallel rows of openings in the securing material to expose respective portions of said semiconductor wafer, said rows of openings being aligned with a selected crystal plane of said semiconductor wafer; the method including anisotropically etching the regions of the semiconductor wafer exposed by each row of openings to form rows of trenches in each of the opposite sides of said semiconductor wafer, each row of trenches being aligned with a corresponding row of trenches in an opposite side of said semiconductor wafer such that each aligned pair of rows of trenches meets during continued etching to form a continuous corresponding one of said parallel elongate openings through said semiconductor wafer.

32. The method of claim 27, wherein the gaps between adjacent openings in each row of openings in the securing material are substantially equal to the width of the openings.

33. The method of claim 27, wherein the opposite ends of the openings are orthogonal to a (111) direction of the semiconductor wafer, the gaps between adjacent openings in each row of openings in the securing material being less than about 35% of the width of the openings in the securing material.

34. The method of claim 27, wherein the opposite ends of each opening in the securing material are inclined to the opposite sides of the opening at an angle substantially equal to 19.5°, the gaps between adjacent openings in each row of openings in the securing material being less than about 106% of the width of each opening in the securing material.

35. The method of claim 16, wherein the securing material includes quartz, borosilicate glass, or a semiconductor.

36. The method of claim 1, wherein the securing means engages opposite edges of each elongate substrate.

37. The method of claim 36, including removing a wafer frame interconnecting said elongate substrates to provide a plurality of independent elongate substrates secured only by said securing means.

38. The method of claim 37, including processing the independent elongate substrates secured only by said securing means to form devices in said independent elongate substrates.

39. The method of claim 36, wherein the elongate substrates are arranged in groups of parallel elongate substrates; the method including forming openings through the wafer and around each group to separate the groups and provide each group as an independent group of elongate substrates bounded and interconnected by a peripheral remaining portion of the wafer.

40. The method of claim 39, including processing the independent groups of elongates substrates to form devices in said elongate substrates.

41. A method for processing elongate substrates, including:
forming a plurality of parallel elongate openings through a semiconductor wafer to form a corresponding plurality of elongate substrates between said openings, each of said elongate substrates having opposite edges coplanar with opposite surfaces of said wafer, opposite faces orthogonal to said wafer surfaces, and opposite ends by which the elongate substrates are interconnected; and
applying a securing apparatus having mutually spaced projections to said elongate substrates so that the projections are disposed between opposing faces of adjacent elongate substrates to prevent adjacent ones of said elongate substrates from touching one another.

42. An apparatus for securing elongate substrates formed in a semiconductor wafer, the elongate substrates being formed in a semiconductor wafer, each of said elongate substrates having opposite edges coplanar with opposite surfaces of said wafer, opposite faces orthogonal to said wafer surfaces, and opposite ends by which the elongate substrates are interconnected, the apparatus comprising
one or more securing members comprising mutually spaced locating features or projections to inhibit relative movement of the elongate substrates or touching of adjacent elongate substrates.

43. The apparatus of claim 42, wherein the locating features include corrugations in a resilient surface of said one or more securing members.

44. The apparatus of claim 42, wherein the securing members engage the edges of the elongate substrates and the locating features are adapted for interposing between respective mutually spaced edges of said elongate substrates.

45. apparatus of claim 42 wherein the mutually spaced projections comprise a plurality of mutually spaced projections and wherein the plurality of mutually spaced projections are adapted for interposing between opposing faces of adjacent elongate substrates.

46. A method for processing elongate substrates in a circular wafer comprising forming a plurality of sets of elongate substrates in said wafer, each of said substrates comprising a plurality of elongate substrates of equal length, wherein the elongate substrates occupy greater than 63% of said wafer.

47. The method of claim 46, wherein said circular wafer comprises at least three sets of elongate substrates, wherein said sets include a first set located about a central region of said wafer, and at least two other sets disposed about first said set, each of the at least two other sets including a plurality of elongate substrates having a length substantially less than the diameter of said wafer.

48. The method of claim 47, wherein said first set includes a plurality of elongate substrates having a length substantially equal to a diameter of said wafer.

49. The method of claim 47, wherein each of said at least two other sets includes a plurality of elongate substrates parallel to the elongate substrates of said first set, each having a length substantially equal to a chord of said wafer coincident with an elongate substrate of the set farthest from said first set.

50. The method of claim 49, wherein each of said at least two other sets includes a plurality of elongate substrates parallel to the elongate substrates of said first set.

51. The method of claim 46, comprising forming three sets of elongate substrates in a circular wafer, two of the three sets including a plurality of parallel elongate substrates the third set including a plurality of parallel elongate substrates and being oriented at an angle of 70.5° to the other elongate substrates.

52. The method of claim 51, wherein said elongate substrates occupy at least about 80% of said wafer.
